(19) United States
(12) Patent Application Publication
(10) Pub. No.: US 2025/0113680 A1
(43) Pub. Date: Apr. 3, 2025

(54) METHOD FOR MANUFACTURING A SEMICONDUCTOR ARRANGEMENT AND SEMICONDUCTOR ARRANGEMENT

(71) Applicant: ams-OSRAM International GmbH, Regensburg (DE)

(72) Inventors: Andreas Ploessl, Regensburg (DE); Norwin von Malm, Nittendorf (DE)

(21) Appl. No.: 18/834,575

(22) PCT Filed: Jan. 27, 2023
(86) PCT No.: PCT/EP2023/052082

§ 371 Date: Jul. 30, 2024

(30) Foreign Application Priority Data
Feb. 1, 2022 (DE) 10 2022 102 362.1

(51) Int. Cl. H10H 20/857; H10H 20/819; H10H 29/01; H10H 29/14

(52) U.S. Cl. CPC H10H 20/857; H10H 20/819; H10H 29/011; H10H 29/0364; H10H 29/14

(57) ABSTRACT

In an embodiment a semiconductor arrangement includes at least one semiconductor component with a functional layer stack. The functional layer stack includes a first layer of a first conductivity type, a second layer of a second conductivity type arranged on the first layer, an active zone located between the first and the second layer and an electrically conductive nanowire layer, wherein the electrically conductive nanowire layer is arranged at least in regions on a side of the second layer facing away from the first layer. The semiconductor arrangement further includes a holding layer with at least one elevation, wherein the at least one semiconductor component is arranged on the at least one elevation such that a cavity is formed between the at least one semiconductor component and the holding layer, and wherein the nanowire layer is at least partially exposed.

### CROSS-REFERENCE TO RELATED APPLICATIONS

This patent application is a national phase filing under section 371 of PCT/EP2023/052082, filed Jan. 27, 2023, which claims the priority of German patent application 10 2022 102 362.1, filed Feb. 1, 2022, each of which is incorporated herein by reference in its entirety.

### TECHNICAL FIELD

The present invention relates to a method for manufacturing a semiconductor arrangement comprising at least one semiconductor component, a semiconductor arrangement comprising at least one semiconductor component, a method of manufacturing an optoelectronic device comprising a plurality of semiconductor components, and an optoelectronic device comprising a plurality of semiconductor components.

### BACKGROUND

Semiconductor components, such as LEDs, lasers, ICs or sensors, can be placed from a donor substrate onto, for example, electrical contact surfaces of a target substrate using a transfer printing process. In addition to a mechanical connection, an electrical and, in particular, thermal coupling of the semiconductor components with the contact surfaces is also required. The constant further development in the field of semiconductor components, and in particular the desired increasing miniaturization of semiconductor components or the devices comprising the semiconductor components, also requires very precise placement of the semiconductor components at the positions provided for this purpose.

From a production engineering perspective, however, these requirements create a certain conflict of objectives. In general, precise placement of semiconductor components is possible under ambient conditions with a constant temperature close to room temperature, whereas reliable electrical or thermal contact is generally more likely to be achieved at elevated temperatures. The precise placement of semiconductor components on a target substrate, in particular by means of a transfer printing process, at room temperature and simultaneously robust mechanical and electrical coupling of the semiconductor components on the target substrate is therefore an unsolved problem that will be addressed in the following.

Only multi-stage processes are known from the prior art, in which the setting of the semiconductor components comprises, for example, a transfer process and a contacting process. The transfer process, i.e. the lifting of the semiconductor components from a donor substrate and the transfer of the semiconductor components to a target substrate, can take place at room temperature. However, the semiconductor components are only deposited on the target substrate, so that only a weak mechanical coupling, preferably by sticky plastic layers on the target substrate, is achieved between the semiconductor components and the target substrate. Only in a second step, the contacting process, are the semiconductor components pressed onto contact surfaces on the target substrate at an elevated temperature in such a way that the sticky plastic layer is penetrated locally by roughness peaks of the contact surfaces of the semiconductor components and roughness peaks of the contact surfaces of the target substrate, thus forming electrical contacts. At the same time, the increased temperature and subsequent cooling causes the sticky plastic layer to harden.

However, the second step not only represents an expensive additional expense due to the “extra step”, but also often leads to the misalignment of chips. Precise placement of the semiconductor components cannot be guaranteed, meaning that the type and quality of products that can be manufactured using such a process is limited.

### SUMMARY

Embodiments provide a method for manufacturing at least one semiconductor arrangement comprising at least one semiconductor component, as well as a semiconductor arrangement comprising at least one semiconductor component, which counteracts at least one of the aforementioned problems. Further embodiments provide a method for manufacturing an optoelectronic device comprising a plurality of semiconductor components, as well as an optoelectronic device comprising a plurality of semiconductor components, which also counteracts at least one of the aforementioned problems.

Semiconductor components suitable for transfer printing processes have so far been equipped with flat metal surfaces or with metal layers of essentially constant thickness as electrical contact surfaces. In contrast, the inventors propose using easily deformable metal layers as electrical contact surfaces, which have a clear 3D structure, such as porous or turf-like metal layers or metal layers with nanowires. In addition, the inventors propose that the receiving surfaces/electrical contact surfaces on the target substrate also have easily deformable metal layers. The easily deformable electrical contact surfaces or metal contacts allow the semiconductor components to be coupled mechanically, thermally and electrically in a single step during transfer printing by placing and pressing them onto the receiver substrate. The easy deformability of the electrical contact surfaces enables a metallic or mechanical and electrical connection of the electrical contact surfaces at or near room temperature.

However, due to the easy deformability of the electrical contact surfaces, it must be ensured during the manufacturing process of the semiconductor components that the semiconductor components can be removed from a donor substrate without damaging the easily deformable layers. For this purpose, the contact surfaces are first deposited on the semiconductor components in an embedded and thus safe state, and then a sufficiently deep cavity is created under the semiconductor components using a transfer tool, such as a stamp, before the semiconductor components are removed, so that the easily deformable electrical connection surfaces are essentially free-floating on the semiconductor components.

According to at least one embodiment, a method of manufacturing a semiconductor arrangement comprises the steps of:
Providing a functional layer stack comprising a carrier substrate, a first layer of a first conductivity type disposed on the carrier substrate, a second layer of a second conductivity type disposed on the first layer, and an active zone disposed between the first and second layers;
Forming an electrically conductive nanowire layer, at least in certain areas, on a side of the second layer facing away from the carrier substrate;
Forming a structured sacrificial layer on the nanowire layer with at least one opening, wherein the at least one opening extends at least through the sacrificial layer and optionally at least partially through the nanowire layer;
Optionally forming a separating layer on the sacrificial layer, the separating layer being arranged at least partially in the at least one opening;
Forming a holding layer on the structured sacrificial layer or the optional release layer, wherein the holding layer is at least partially disposed in the at least one opening;
Structuring the functional layer stack to produce at least one semiconductor component such that at least one well is formed through the functional layer stack; and
Removing the sacrificial layer so that a cavity is formed between the at least one semiconductor component and the holding layer and the nanowire layer is at least partially exposed.

A semiconductor arrangement comprising at least one semiconductor component, such as a micro-LED, can be produced by such a process. The at least one semiconductor component can, for example, be grown on the basis of gallium nitride, comprises an easily deformable electrical contact surface, for example in the form of a turf-like metal connection surface or nanowire layer, and is particularly suitable for a transfer printing process. The semiconductor arrangement or the holding layer of the semiconductor arrangement acts as a donor substrate, from which at least one semiconductor component can be removed by means of a transfer printing process, for example, and placed on a target substrate.

According to at least one embodiment, a functional layer stack is deposited or grown as usual on an epitaxial substrate, hereinafter referred to as carrier substrate, and doped and/or structured depending on the application and requirements. The functional layer stack comprises at least a first layer of a first conductivity type arranged on the carrier substrate, a second layer of a second conductivity type arranged on the first layer, and an active zone located between the first and second layers. The first conductivity type can be an n-doping of the first layer and the second conductivity type can be a p-doping of the second layer. However, doping in the reverse order is also conceivable. In addition, the functional layer stack can comprise current expansion layers on the first or second layer. The semiconductor component is then formed from the functional layer stack in a later step.

According to at least one embodiment, a starting layer, for example a 200 nm thick Au layer, is then applied over the entire surface of the side of the second layer facing away from the carrier substrate for subsequent formation of the nanowire layer. In particular, the starting layer can be an electrically conductive layer that allows subsequent electroplating of a metal in the pores of an ion track-etched film in order to produce the nanowires of the nanowire layer. Such a layer can serve to provide a better mechanical, electrical as well as thermal connection between the functional layer stack and the nanowire layer and can be formed, for example, by sputtering.

According to at least one embodiment, before the nanowire layer is formed on the side of the second layer facing away from the carrier substrate or the starting layer, areas in which the nanowire layer is not to be formed are also masked, for example with a thin photoresist or silicon nitride layer. According to at least one embodiment, a structured mask is accordingly formed on the side of the second layer or the starting layer facing away from the carrier substrate before the nanowire layer is formed. The electrically conductive nanowire layer can then be formed on the side of the second layer or the starting layer facing away from the carrier substrate in the areas that remain free of the structured mask.

It is also possible that the structured mask is first formed on the side of the second layer facing away from the carrier substrate, and then the starting layer is formed or applied in areas that remain free of the structured mask. The starting layer can accordingly be present in structured form on the carrier substrate.

According to at least one embodiment, an ion track-etched film is applied to the side of the second layer or the starting layer facing away from the carrier substrate to form the nanowire layer. In the case of a structured mask on the second layer or the starting layer, the ion track-etched film can only be applied in the areas that remain free of the structured mask. Alternatively, the ion track-etched film can also be applied over the entire surface of the structured mask. Depending on the thickness of the structured mask or film and the size of the areas left free of the structured mask, applying the ion track-etched film over the entire surface can result in the film conforming to the topography of the structured mask, so that the film also extends into the areas left free. According to a further embodiment, however, the film applied over the entire surface lies on the structured mask and areas that remain free of the structured mask also remain free of the ion track-etched film.

The ion-track-etched film can, for example, be formed by a filter film, such as polycarbonate (PC), polyimide (PI) or polyethylene terephthalate (PET), and can serve as a mask for the electrodeposition of “metal straws” or nanowires, as these have cavities or through-holes due to the ion-track etching, which can then be filled with an electrically conductive material. When the foil is removed after the cavities or through-holes have been filled with an electrically conductive material, this remains in the form of periodically or randomly arranged “metal straws” or nanowires. The “metal straws” or nanowires can be aligned more or less parallel to each other. The distribution of the angles formed by the pores or through-holes with the film surface can vary depending on the film used. Such films can have a thickness of up to 25 μm or even greater with cavities or through-holes with a diameter of 15 nm and greater. For embodiments of the present invention, for example, a PC film with a pore or cavity diameter of 100 nm can be used in a preferred manner, so that metal straws, for example gold (Au) straws, with a diameter of 100 nm and a length of approx. 2 μm can be produced. However, the metal straws can also be made of silver (Ag), copper (Cu) or a correspondingly soft metal alloy. In particular, the foil can be selected so that metal straws with a diameter of less than 1 μm or less than 200 nm can be produced that are at least 8 times or at least 10 times longer than the diameter.

According to at least one embodiment, the application of the film on the side of the second layer or the starting layer facing away from the carrier substrate comprises the application of a carrier material such as PC, PI or PET and subsequent etching of cavities or through-holes in the carrier material by ion irradiation. The ion track-etched film can also be produced on the second layer or the starting layer.

According to at least one embodiment, an electrically conductive material is electroplated onto the film to form the nanowire layer. As a result, the cavities or through-holes in the film are filled with the electrically conductive material and the “metal straws” or nanowires are formed. In the event that the ion track-etched film is applied over the entire surface of a structured mask in such a way that areas that remain free of the structured mask also remain free of the ion track-etched film, these areas can be filled with the electrically conductive material by electrodepositing an electrically conductive material on the ion track-etched film before the cavities or through-holes of the film are filled with the electrically conductive material. holes in the film are filled with the electrically conductive material and the “metal straws” or nanowires are formed accordingly.

According to at least one embodiment, in the case of a structured mask, the ion track-etched foil is not applied in all areas that remain free of the structured mask. For example, areas can also remain free of both the structured mask and the film, which are then filled with the electrically conductive material during the electrodeposition process. As a result, in addition to the areas of the nanowire layer, i.e. easily deformable areas, there are also areas that are less easily deformable as they are formed by a more solid formation of the electrically conductive material. These more solid areas can then serve as an attachment point for the holding layer or the separating layer in the area of the at least one opening through the sacrificial layer.

According to at least one embodiment, the step of forming the nanowire layer comprises chemo-mechanically thinning or polishing the nanowire layer. In particular, after galvanic deposition, chemo-mechanical “polishing” is performed down to the “metal straws” or nanowires. By thinning the nanowire layer, residues of the electrodeposition that are present on the foil and that connect the individual “metal straws” or nanowires to each other are removed. In particular, the thinning is carried out in such a way that the “metal straws” or nanowires in the nanowire layer are then separated from each other or are only connected to each other by the second layer or the starting layer.

According to at least one embodiment, the nanowire layer can also be formed by a porous layer that has a porosity above 70%. The porous layer can be formed by electrodeposition of an electrically conductive material on a porous film. The nanowire layer can also be formed, for example, by a finely branched network of electrically conductive material, in particular with local material accumulations (pores). The nanowire layer can be characterized, for example, by the fact that it is compressible compared to a conventional electrically conductive contact layer due to its porosity.

According to at least one embodiment, the foil or, in the case of a structured mask, the mask is removed or etched away in areas that lie between semiconductor components that are formed later. Alternatively or additionally, the nanowire layer and/or the starting layer can also be removed or etched away in areas that lie between semiconductor components that are formed later.

According to at least one embodiment, a metal alloy, for example an Au—Ag or an Ag—Cu alloy, is deposited on the side of the second layer or the starting layer facing away from the carrier substrate to form the nanowire layer. The less noble component of the alloy can then be removed from the alloy to form pores, for example to form a finely branched network of electrically conductive material, in particular with local material accumulations (pores). The step of removing the less noble component of the alloy can take place before the step of forming the sacrificial layer or after the step of removing the sacrificial layer.

According to at least one embodiment, a sacrificial layer is deposited on the nanowire layer. The sacrificial layer may, for example, be a germanium or silicon sacrificial layer. The sacrificial layer is either deposited in a structured manner or subsequently structured after the deposition of a continuous surface. In particular, the sacrificial layer is structured in such a way that it subsequently comprises at least one opening that extends through the sacrificial layer and optionally also at least partially through the nanowire layer or starting layer or the structured mask. The at least one opening is arranged in particular in an area in which a support formed later by means of the separating layer and the holding layer holds the at least one semiconductor component in position.

According to at least one embodiment, a part of the sacrificial layer is used as such instead of the film. A first part of the sacrificial layer forms the film. For this purpose, a first part of the sacrificial layer is deposited on the side of the second layer or the starting layer facing away from the carrier substrate. For example, an approximately 2.2 μm thick silicon layer can be deposited on the second layer or the starting layer and cavities or through-holes or pores with an average diameter of 125 nm, for example, can be electrochemically etched into the first part of the sacrificial layer. An electrically conductive material is then electroplated onto the first part of the sacrificial layer and the cavities, through-holes or pores are filled with the electrically conductive material. After the electroplating step, the previously described step of exposing the nanowire layer by means of chemomechanical thinning or polishing of the nanowire layer can optionally take place before a continuous second part of the sacrificial layer is applied to the first part of the sacrificial layer. Such a procedure has the advantage that the sacrificial layer and the foil can be removed simultaneously using only one step or one etching medium.

According to at least one embodiment, the foil also forms the sacrificial layer. In such a case, the separating layer would adjoin the nanowire layer or the foil over a large area and hold the at least one semiconductor component in position accordingly from the time of removal of the sacrificial layer or, in this case, from the time of removal of the foil. Such a holding structure only via the nanowire layer can also be reinforced by means of additional metallic holding structures, which are created by inserting larger through-holes through the foil and subsequently filling them during electrodeposition.

According to at least one embodiment, a release layer resistant to an etching medium for later removal of the sacrificial layer, for example silicon dioxide (SiO₂), is applied over the entire surface of the sacrificial layer. In particular, a thin release layer with a thickness of, for example, 50 nm to 300 nm is applied to the sacrificial layer in such a way that it is also partially arranged in the at least one opening and preferably covers the entire contour of the sacrificial layer facing away from the functional layer stack. The release layer serves in particular as a contact layer for the holding layer applied to the release layer in the next step, as well as a protective layer for the same, in order to protect the holding layer against the etching medium for subsequent removal of the sacrificial layer.

According to at least one embodiment, the step of forming the holding layer on the release layer comprises adhering the holding layer to the release layer. However, it is also possible that the holding layer is formed by polymerization on the release layer. For example, divinylsiloxane-bis-benzocyclobutene in mesitylene (cyclotene) can be applied to the release layer and polymerized to form benzocyclobutene. Alternatively or additionally, PI layers can also be used for the holding layer. However, the holding layer is arranged at least partially in the at least one opening and, together with the release layer in the region of the at least one opening, forms a support which holds the at least one semiconductor component, which is formed from the functional layer stack in subsequent steps, in position. The holding layer serves in particular as a carrier substrate for the at least one semiconductor component and also functions as a donor substrate for a possible subsequent transfer printing process for transferring the at least one semiconductor component from the donor substrate to a target substrate.

According to at least one embodiment, after the step of forming the holding layer, the layer stack formed up to that point is rotated and the epitaxial substrate or carrier substrate of the functional layer stack, for example a sapphire substrate, is detached. The carrier substrate of the functional layer stack can be detached using a laser lift-off process, for example. The first layer, or the side of the first layer facing away from the second layer, can then be processed further, for example to form a current expansion layer and/or an electrically conductive and in particular at least semi-transparent contact layer on the first layer.

According to at least one embodiment, the functional layer stack is structured to produce at least one semiconductor component by introducing or etching into it at least one indentation which separates at least one semiconductor component from the rest of the functional layer stack or further semiconductor components. In particular, the at least one indentation extends through the entire functional layer stack up to the sacrificial layer or, in the area of the at least one opening, up to the optional separating layer. At least one semiconductor component, or even two or more semiconductor components, is produced by structuring the functional layer stack or introducing the at least one recess.

According to at least one embodiment, the step of structuring the functional layer stack comprises mesa etching the functional layer stack to produce at least one semiconductor component. The at least one indentation is produced by means of the mesa etching and is accordingly formed by at least one mesa trench. The at least one mesa trench is essentially conical or tapering in the direction of the sacrificial or separating layer. The resulting at least one semiconductor component accordingly has a mesa structure.

According to at least one embodiment, the step of removing the sacrificial layer is carried out by dissolving it out, for example with hydrogen fluoride (HF) or xenon difluoride (XeF2). For example, it may be necessary to form accesses to the buried sacrificial layer beforehand. Removing the sacrificial layer results in a cavity between the at least one semiconductor component and the holding layer or the separating layer, and the at least one semiconductor component is no longer connected to the optional separating layer or the holding layer via the sacrificial layer, but only in the area of the at least one opening or support.

According to at least one embodiment, after or during the step of removing the sacrificial layer, the foil is also removed by etching, for example using chlorine trifluoride (CIF₃) or an organic solvent, so that the nanowire layer and in particular the “metal straws” or nanowires are at least partially exposed.

According to at least one embodiment, the foil is removed before the step of depositing the sacrificial layer on the nanowire layer. The cavities or through-holes or pores between the nanowires or metal straws of the nanowire layer are then—at least partially—filled with the material of the sacrificial layer during the step of depositing the sacrificial layer on the nanowire layer. As a result, only one step or one etching medium is required at a later time to remove the entire sacrificial layer and expose the nanowires or metal straws of the nanowire layer.

According to at least one embodiment, the at least one opening through the sacrificial layer and the at least one recess through the functional layer stack are essentially directly opposite each other. In particular, a support formed by the holding layer or separating layer in the region of the at least one opening can hold the at least one semiconductor component in an edge region thereof. In the case of several semiconductor components, the support formed by the holding layer or separating layer can, for example, hold the semiconductor components separated by the at least one recess and adjacent to the support.

According to at least one embodiment, however, the at least one opening through the sacrificial layer and the at least one recess through the functional layer stack are arranged offset to one another. For example, each semiconductor component can be assigned its own support, which is formed in the at least one opening and which holds the semiconductor component after removal of the sacrificial layer. The support can, for example, be arranged in the center of the semiconductor component, but also off-center from it.

The at least one semiconductor component or several semiconductor components in the semiconductor arrangement produced in this way can then be collectively picked up with a transfer stamp and detached from the semiconductor arrangement or the support in order to be subsequently transferred to a target substrate.

Furthermore, a semiconductor arrangement is proposed which comprises at least one semiconductor component with a functional layer stack, wherein the functional layer stack has a first layer of a first conductivity type, a second layer of a second conductivity type arranged on the first layer, an active zone located between the first and the second layer, and an electrically conductive nanowire layer, and wherein the electrically conductive nanowire layer is arranged at least regionally on a side of the second layer facing away from the first layer. The semiconductor arrangement also comprises a holding layer with at least one elevation and a separating layer optionally arranged on the holding layer. The at least one semiconductor component is arranged on the at least one elevation or support in such a way that a cavity is formed between the at least one semiconductor component and the holding layer and the nanowire layer is at least partially exposed.

Such a semiconductor arrangement comprising at least one semiconductor component can, for example, serve as a donor substrate from which the at least one semiconductor component can be removed by means of, for example, a transfer printing process and placed on a target substrate. The at least one semiconductor component can be a micro-LED, for example, which is grown on the basis of gallium nitride and which has an easily deformable electrical contact surface, for example in the form of a turf-like metal connection surface or nanowire layer.

According to at least one embodiment, the at least one semiconductor component has a mesa structure, wherein at least one mesa trench or at least one recess for delimiting the at least one semiconductor component extends through the entire functional layer stack as far as the cavity or, in the region of the at least one elevation or support, as far as the separating layer. The at least one mesa bar runs essentially conically or tapered in the direction of the cavity or the separating layer.

According to at least one embodiment, the at least one semiconductor component has an electrically conductive and, in particular, at least semi-transparent contact layer on the side of the first layer facing away from the second layer. The contact layer can, for example, be formed from a material such as indium tin oxide (ITO) and, in addition to the electrically conductive nanowire layer, provide an electrical connection surface for the at least one semiconductor component. The at least one semiconductor component can accordingly be electrically connectable to two opposite sides of the semiconductor component and accordingly have a so-called “vertical current conduction”.

According to at least one embodiment, the at least one semiconductor component is formed by a light-emitting or light-detecting component. The at least one semiconductor component can, for example, be an LED or an LED chip or a photodiode. In particular, the LED or LED chip can also be referred to as a micro-LED, also known as a uLED, or as a uLED chip, especially if its light-emitting surface comprises edge lengths in the range from 100 μm to 10 μm or even significantly smaller edge lengths. In some embodiments, the LED or the LED chip can be an unhoused semiconductor chip. Unhoused means that the chip does not have a package around its semiconductor layers, such as a “chip die”. In some embodiments, unhoused may mean that the chip is free of intentionally applied layers or wrappings comprising an organic material. Thus, the unhoused device does not include layers or claddings comprising organic compounds containing carbon in a covalent bond. For example, the unhoused device does not contain any silicone, epoxy or imide coatings.

The at least one semiconductor component can, for example, be designed to emit light in the vertical direction, i.e. through the at least semi-transparent contact layer, or to detect light that impinges on the at least semi-transparent contact layer. However, it is also conceivable that the at least one semiconductor component in the form of a volume emitter is designed to emit light in both the vertical and lateral directions, or that the at least one semiconductor component in the form of an edge emitter is designed to emit light only in the lateral direction.

According to at least one embodiment, the at least one semiconductor component further comprises a starting layer formed between the second layer and the nanowire layer. Such a layer may serve to provide a better mechanical, electrical as well as thermal connection between the functional layer stack and the nanowire layer and may be formed, for example, by means of sputtering. For example, the starting layer and the nanowire layer can be formed from the same material and merge into each other so that the individual nanowires of the nanowire layer are essentially connected to each other via the starting layer.

According to at least one embodiment, the nanowire layer of the at least one semiconductor component covers substantially the entire side of the second layer facing away from the first layer. In this way, a particularly large-area electrical contact surface can be provided on the at least one semiconductor component. However, it is also possible for the nanowire layer on the second layer to be structured. By structured, however, is not meant structuring in the form of individual nanowires, but rather that in addition to the nanowires, areas are present on the second layer that remain free of the nanowire layer. For example, different electrical contact surfaces can be provided on one side of the at least one semiconductor component, or material can simply be saved due to a reduction in the area covered with nanowires.

According to at least one embodiment, a plurality of “metal straws” or nanowires are present separately from one another within the nanowire layer of the at least one semiconductor component. These can be arranged either periodically or randomly in relation to one another. The individual metal straws, for example Au straws, can have a diameter of 100 nm and a length of approx. 2 μm.

According to at least one embodiment, the semiconductor arrangement comprises at least two semiconductor components which are arranged next to one another on the at least one elevation or support, separated from one another by a recess, for example in the form of a mesa trench. The recess for separating the two semiconductor components extends through the entire functional layer stack up to an optional separating layer arranged on the at least one elevation and runs essentially conically or tapered in the direction of the separating layer. The recess and the elevation are essentially directly opposite each other. In particular, the elevation formed by the holding layer or separating layer is designed to hold the at least two semiconductor components separated by the recess.

According to at least one embodiment, the semiconductor arrangement comprises at least two semiconductor components which are separated from each other by a recess, for example in the form of a mesa bar, and are arranged next to each other on a separate elevation of the holding layer. The elevation or support can be arranged in the center of the semiconductor components, but also off-center.

A method of manufacturing an optoelectronic device is further proposed, comprising the steps of:
Providing a semiconductor arrangement, in particular a semiconductor arrangement according to some of the aforementioned aspects, comprising at least one semiconductor component with an electrically conductive nanowire layer arranged on the side of the semiconductor component facing the holding layer. The at least one semiconductor component is arranged on at least one elevation of a holding layer in such a way that a cavity is formed between the at least one semiconductor component and the holding layer and the nanowire layer is at least partially exposed. An optional separating layer can also be formed on the holding layer or between the holding layer and the at least one semiconductor component;
Lifting the at least one semiconductor component from the at least one elevation or support; and
Depositing the at least one semiconductor component on a first contact surface of a printed circuit board, the printed circuit board having a contact structure with a plurality of contact surfaces on its top surface.

According to at least one embodiment, at least the first contact surface of the plurality of contact surfaces has an electrically conductive nanowire layer.

The electrically conductive nanowire layer of the at least one first contact surface can be a nanowire layer as already described for the semiconductor arrangement or semiconductor component. However, it can also be a porous layer or a finely branched network of electrically conductive material, in particular with local material accumulations (pores). Alternatively, it is also possible for the first contact surface to be formed by a conventional flat metal layer or contact surface.

The process can, for example, be a transfer printing process for transferring at least one semiconductor component from a semiconductor arrangement comprising the semiconductor component (donor substrate) to a printed circuit board (target substrate). However, due to the nanowire layer on both the semiconductor component and the printed circuit board, the process is simplified compared to currently used transfer printing processes. The easily deformable electrical contact surfaces in the form of the nanowire layers allow the semiconductor components to be coupled mechanically, thermally and electrically in a single step during transfer printing by placing and pressing them onto the printed circuit board. The easy deformability of the electrical contact surfaces enables a metallic or mechanical and electrical connection of the electrical contact surfaces at or near room temperature. A multi-stage process as known from the prior art, in which the setting of the semiconductor components comprises a transfer process and a contacting process, is therefore no longer required, but the setting of the semiconductor components essentially takes place in a single process step at or near room temperature.

According to at least one embodiment, the step of lifting the at least one semiconductor component from the semiconductor arrangement or the holding layer is carried out by means of a stamp. The at least one semiconductor component or also several semiconductor components are picked up by a stamp and torn off the semiconductor arrangement or the holding layer. The contact area between the semiconductor component and the elevation or support, which is relatively small compared to the size of the semiconductor components, acts like a predetermined breaking point at which the semiconductor component is torn off. This ensures that only a small force is required to lift off the at least one semiconductor component and that the at least one semiconductor component, and in particular the nanowire layer, is not damaged when it is lifted off.

According to at least one embodiment, the step of depositing the at least one semiconductor component comprises fixing the at least one semiconductor component to the first contact surface by pressing the at least one semiconductor component onto the first contact surface. Due to the turf-like structure of the nanowire layers and due to the easy deformability of the nanowire layers, a contact pressure of less than 1 MPa and preferably less than 0.3 MPa is sufficient to generate a mechanical, thermal and electrical contact between the at least one semiconductor component and the first contact surface.

According to at least one embodiment, the fixing of the at least one semiconductor component is carried out essentially without a temperature-induced process, in particular by “cold welding”. The deformation of the metal structures, which leads to “cold welding”, can be carried out at or near room temperature. Cold welding at room temperature and low pressure is more successful if the deformable structures have little or no contamination. In particular, the nanowire layers cannot be stabilized with a protective coating, but are only exposed after or during the removal of the sacrificial layer or the free etching of the cavities. The metal straws or nanowires of the nanowire layer remain in the semiconductor arrangement in the film until after the cavities have been etched free.

According to at least one embodiment, the semiconductor arrangement comprises a plurality of semiconductor components. At least a number of the plurality of semiconductor components are then lifted from the semiconductor arrangement by means of the process or by means of a stamp and deposited on first contact surfaces of the printed circuit board. The optoelectronic semiconductor components each have an electrically conductive nanowire layer on a bottom surface facing the contact structure, at least in some areas, which is in electrically conductive contact with an electrically conductive nanowire layer of the first contact surfaces of the printed circuit board or is brought into contact by pressing.

By means of the proposed method, a precise and yet simplified assembly of at least one or more semiconductor components with large-area metallic coupling in the transfer printing process can be provided at the same time. Misalignment of the at least one or more semiconductor components by subsequent processes, such as remelting in the case of solder contacts or thermocompression, is eliminated, and problems caused by a transfer printing process with high temperatures used are completely avoided.

An optoelectronic device is further proposed comprising a printed circuit board having a contact structure with a plurality of contact surfaces arranged on the top surface thereof. In addition, the optoelectronic device comprises a plurality of semiconductor components, each of which is arranged on one of the plurality of contact surfaces. The semiconductor components each have an electrically conductive nanowire layer on a bottom surface facing the contact structure, at least in certain areas, which is in electrically conductive contact with the contact surfaces on the top surface of the printed circuit board.

According to at least one embodiment, the contact surfaces on the top surface of the printed circuit board also have an electrically conductive nanowire layer. This is then in electrically conductive contact with the electrically conductive nanowire layer of the semiconductor components.

According to at least one embodiment, the semiconductor components are the semiconductor components of the semiconductor arrangement described in the context of the application or the semiconductor components produced in the context of the described manufacturing process of the semiconductor arrangement, which were transferred from the semiconductor arrangement to the printed circuit board, in particular by means of the process described in this application.

According to at least one embodiment, the semiconductor components each have a mesa structure. In addition, the semiconductor components in particular have a functional layer stack with a first layer of a first conductivity type, a second layer of a second conductivity type arranged on the first layer, and an active zone located between the first and the second layer.

According to at least one embodiment, the semiconductor components are each formed by optoelectronic semiconductor components or by light-emitting or light-detecting components. The semiconductor components can, for example, each be formed by an LED or an LED chip or a photodiode. In particular, the LED or LED chip can also be referred to as a micro-LED, also known as a uLED, or as a uLED chip, especially if its light-emitting surface has edge lengths in the range from 100 μm to 10 μm or even significantly smaller edge lengths. In some embodiments, the LED or the LED chip can be an unhoused semiconductor chip.

According to at least one embodiment, the optoelectronic semiconductor components each have an electrically conductive and, in particular, at least semi-transparent contact layer on a side of the semiconductor component opposite the printed circuit board.

The semiconductor components can, for example, be designed to emit light in the vertical direction, i.e. through the at least semi-transparent contact layer, or to detect light that impinges on the at least semi-transparent contact layer. However, it is also conceivable that the semiconductor components in the form of a volume emitter are designed to emit light in both the vertical and lateral directions, or that the semiconductor components in the form of an edge emitter are designed to emit light only in the lateral direction.

According to at least one embodiment, the semiconductor components each comprise a starting layer formed between a functional layer stack of the semiconductor component and the nanowire layer.

According to at least one embodiment, the nanowire layer of the semiconductor components covers substantially the entire bottom surface of the semiconductor components facing the contact structure.

According to at least one embodiment, a plurality of nanowires are present separately from each other within the nanowire layer of the semiconductor components.

### BRIEF DESCRIPTION OF THE DRAWINGS

In the following, embodiments of the invention are explained in more detail with reference to the accompanying drawings.

FIGS. 1 to 13 show schematically process steps of a method for manufacturing a semiconductor arrangement according to some aspects of the proposed principle; and

FIGS. 14 to 19 show schematically process steps of a method for manufacturing an optoelectronic device according to some aspects of the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct. Some aspects and features are emphasized by enlarging them. However, terms such as “above”, “above”, “below”, “below”, “larger”, “smaller” and the like are shown correctly in relation to the elements in the figures. It is thus possible to deduce such relationships between the elements on the basis of the figures.

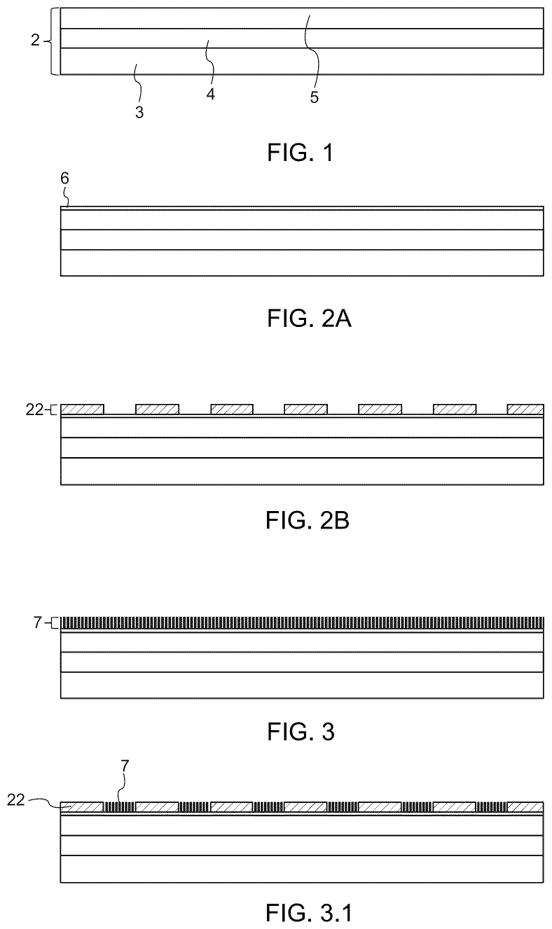

FIGS. 1 to 13 show process steps of a process for manufacturing a semiconductor arrangement according to some aspects of the proposed principle.

In a first step, as shown in FIG. 1, a functional layer stack 2 is provided. The functional layer stack 2 comprises a carrier substrate 3, a first layer 4 of a first conductivity type arranged on the carrier substrate 3, a second layer 5 of a second conductivity type arranged on the first layer 4. An active zone is also arranged between the first and second layers 4, 5. The carrier substrate 3 forms an epitaxial substrate on which the first and second layers 4, 5 are deposited or grown. The functional layer stack 2 can also be doped and/or structured depending on the application and requirements.

For example, the first conductivity type can be an n-doping of the first layer 4 and the second conductivity type can be a p-doping of the second layer 5. However, doping in the reverse order is also conceivable. In addition, the functional layer stack 2 can each comprise current expansion layers on the first or second layer 4, 5 and/or the active zone can have one or more quantum wells (QW). It is also possible that the functional layer stack 2 has quantum well intermixing (QWI) at least in some areas.

In a second step, as shown in FIG. 2A, a starting layer 6 is then applied over the entire surface of the side of the second layer 5 facing away from the carrier substrate 3. The starting layer 6 can be a thin gold, silver or copper layer, for example, which provides a better mechanical, electrical and thermal connection between the functional layer stack 2 and a nanowire layer arranged on it in the subsequent steps.

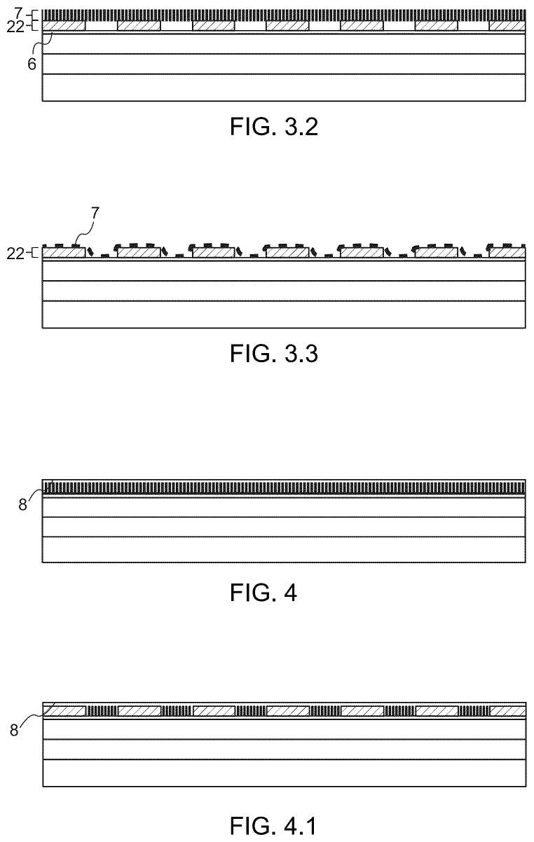

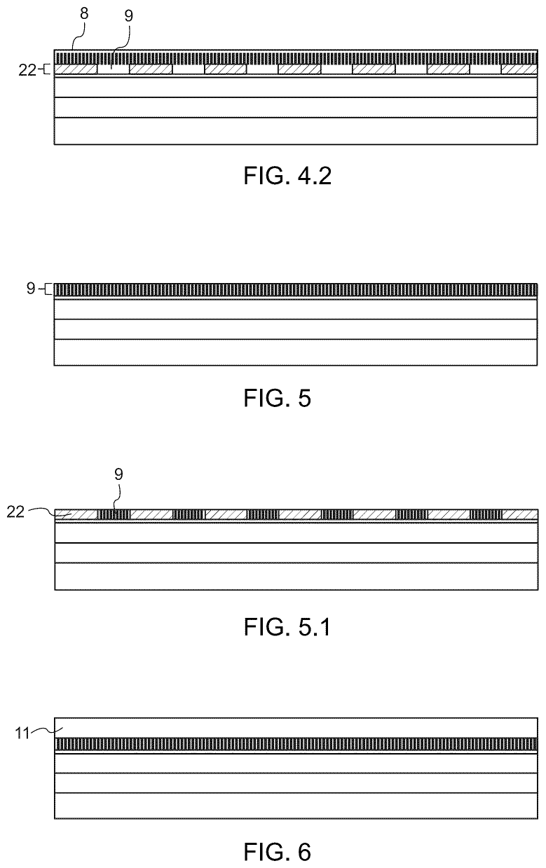

As shown in FIGS. 3, 4 and 5, a nanowire layer 9 is formed on the starting layer 6 in individual intermediate steps. For this purpose, in a first intermediate step, as shown in FIG. 3, an ion-track-etched film 7 is arranged on the starting layer 6. The ion track-etched film 7, for example made of polycarbonate (PC), polyimide (PI) or polyethylene terephthalate (PET), serves as a mask for the electrodeposition of an electrically conductive material 8 to produce “metal straws” or nanowires, as shown in FIG. 4. The ion track-etched film 7 has cavities or through-holes due to ion track etching, which are then filled with the electrically conductive material 8.

In a third intermediate step, as shown in FIG. 5, the electrically conductive material 8 electroplated onto the foil 7 and protruding beyond the foil 7 is then ground off or “polished down” to the “metal straws” or nanowires, so that the “metal straws” or nanowires in the nanowire layer 9 are then separated from each other.

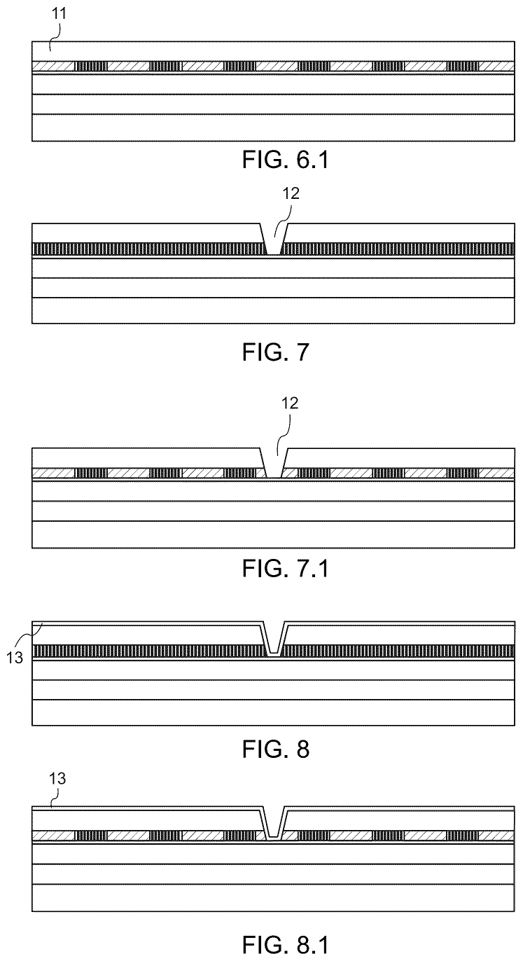

A sacrificial layer 11 is then deposited on the resulting nanowire layer 9, as shown in FIG. 6. The sacrificial layer 11 can be a germanium or silicon sacrificial layer, for example. The sacrificial layer 11 is either already structured and deposited on the nanowire layer 9 or, as shown in this example, subsequently structured after the deposition of a continuous surface (see FIG. 7). The sacrificial layer 11 is structured in such a way that it subsequently has at least one opening 12 that extends through the sacrificial layer 11 and through the nanowire layer 9. The nanowire layer 9 can also be structured so that it also has the opening shown in FIG. 7 before the sacrificial layer 11 is deposited on the nanowire layer 9. The opening 12 is arranged in particular in an area in which a support is formed in subsequent steps, which is intended to hold at least one semiconductor component of the semiconductor arrangement in position.

In a further step, shown in FIG. 8, a thin separating layer 13 is formed on the sacrificial layer 11. The separating layer 13 is characterized by the fact that it is resistant to an etching medium that is used for later removal of the sacrificial layer 11. The separating layer 13 covers the entire surface of the sacrificial layer facing away from the functional layer stack 2 and also covers the inside of the opening 12, so that it is also partially arranged in the opening 12.

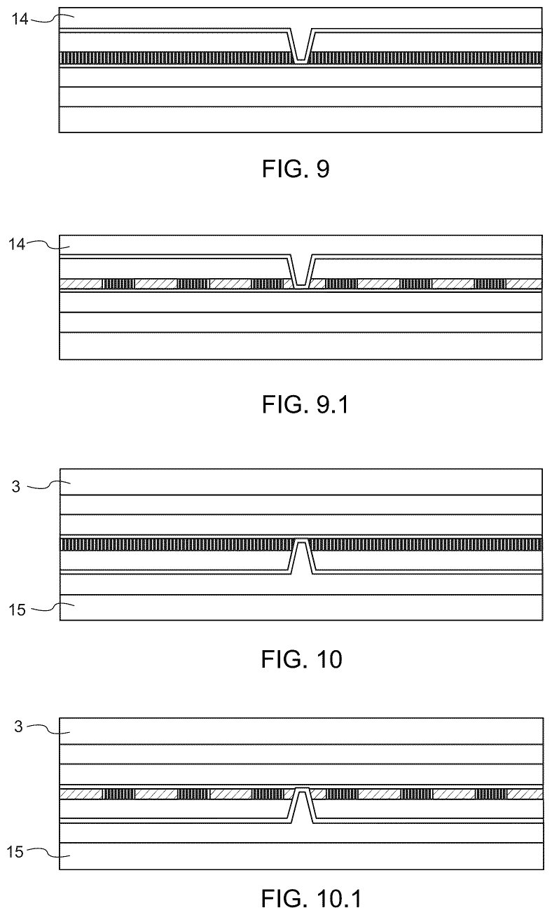

The release layer 13 serves in particular as a contact layer for the holding layer 14 applied to the release layer 13 in the next step shown in FIG. 9, as well as a protective layer for the same in order to protect the holding layer 14 against the etching medium for later removal of the sacrificial layer 11. In the case shown, the holding layer 14 is formed by polymerization on the release layer 13. For example, divinylsiloxane-bis-benzocyclobutene in mesitylene (cyclotene) can be applied to the release layer 13 and polymerized to form benzocyclobutene.

The holding layer 14 is also arranged at least partially in the opening 12 and forms an elevation 23 in this area. Together with the separating layer 13, the elevation of the holding layer forms a support 23, which is intended to hold semiconductor components formed from the functional layer stack 2 in position in subsequent steps.

Then, as shown in FIG. 10, a further auxiliary substrate 15 is applied to the holding layer so that the layer stack created up to that point can be rotated and processed further. The epitaxial substrate or carrier substrate 3 of the functional layer stack 2 is also removed, which can be done using a laser lift-off process, for example.

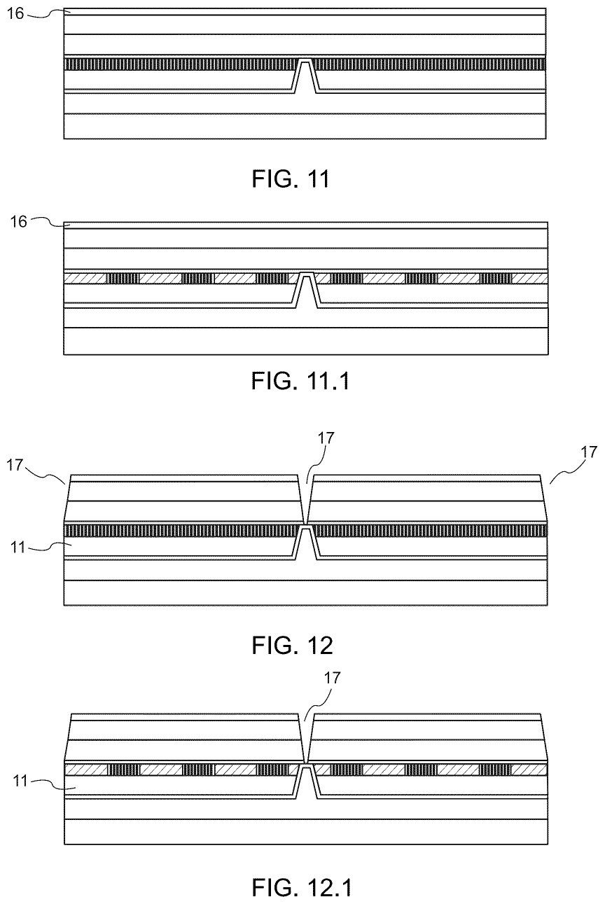

As shown in FIG. 11, an at least semi-transparent contact layer 16, in particular an ITO layer, is formed on the first layer 4 in a next step. Depending on requirements and the application, the first layer 4 or the side of the first layer 4 facing away from the second layer 5 can be processed or, for example, an additional current expansion layer can be formed on it.

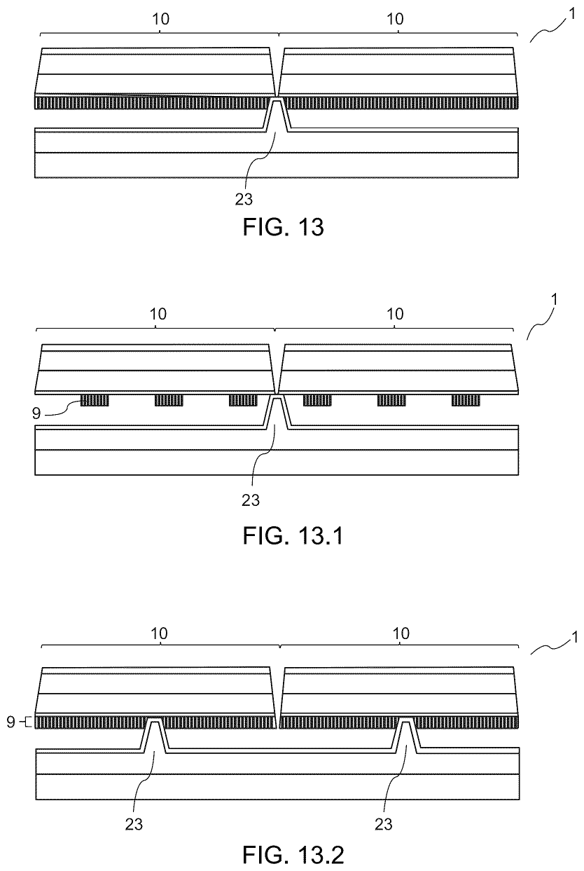

To produce the two semiconductor components 10 shown in FIG. 13, the functional layer stack 2 is structured as shown in FIG. 12. For this purpose, indentations 17 are made or etched into the functional layer stack 2, which then separate the two semiconductor components 10 shown from each other. The indentations 17 extend through the entire functional layer stack 2 as far as the separating layer 13 or the sacrificial layer 11. The indentations 17 are introduced in the course of mesa etching to produce the semiconductor components 10. The indentations 17 form corresponding mesa trenches, which are essentially conical or tapered in the direction of the sacrificial or separating layer 11, 13.

In the example shown in FIG. 12, one of the recesses 17, or more precisely the recess 17 between the two semiconductor components 10, runs centrally opposite the support 23 formed by the retaining and separating layers 13, 14. The semiconductor components thus rest on the support 23 in an edge region of the semiconductor components 10, in particular in a comparatively small contact region.

After structuring the functional layer stack 2, the sacrificial layer 13 is removed or dissolved out in a further step shown in FIG. 13. This can be done using hydrogen fluoride (HF) or xenon difluoride (XeF2), for example. The removal of the sacrificial layer 11 results in a cavity between the semiconductor components 10 and the holding layer 14 or the separating layer 13, and the semiconductor components 10 are no longer connected to the separating layer or the holding layer 13, 14 via the sacrificial layer 11, but only in the area of the support 23. At the same time or after the step of removing the sacrificial layer 11, the foil 7 is also removed by etching, for example using chlorine trifluoride (CIF₃) or an organic solvent, so that the nanowire layer 9 and in particular the “metal straws” or nanowires of the nanowire layer 9 are exposed.

The result of the process steps shown in FIGS. 1 to 13 is the semiconductor arrangement shown in FIG. 13.

FIG. 2B shows an example of a possible process step following the step shown in FIG. 2A. A structured mask 22 is applied to the starting layer 6. The mask can, for example, be formed by a thin photoresist or silicon nitride layer. The mask defines areas in which a nanowire layer 9 is not to be formed in the subsequent process.

FIGS. 3.1 to 13.1 also show process steps subsequent to the process step shown in FIG. 2B for manufacturing at least one semiconductor arrangement 10. The process steps shown in FIGS. 3.1 to 13.1 essentially correspond in each case to the steps shown in FIGS. 3 to 13, with the difference that the electrically conductive nanowire layer 9 is or is only formed in areas that remain free of the structured mask 22. Accordingly, the nanowire layer 9 has a further structure in addition to the nanowires or metal straws. While the nanowires or metal straws can be understood as a type of structuring on a microscopic level, the superordinate structuring of the nanowire layer 9 should be understood as a structuring on a macroscopic level.

However, as shown in FIG. 7.1, the sacrificial layer 11 and the electrically conductive nanowire layer 9 or structured mask 22 are structured or the opening 12 is made in them in such a way that the opening 12 extends through the sacrificial layer 11 and the structured mask 22 and not directly through the nanowire layer 9.

In addition, the method differs from the method described first in that, as shown in FIG. 13.1, in addition to the sacrificial layer 11 and the foil 7, the structured mask 22 is also removed, so that on the one hand the structured nanowire layer 9 and on the other hand the individual nanowires or metal straws in the structured nanowire layer 9 are exposed. FIG. 13.1 shows a further embodiment of the semiconductor arrangement 1 corresponding to FIG. 13.

FIG. 3.2 shows an alternative to the step shown in FIG. 3.1 and differs from FIG. 3.1 in that the ion track-etched foil 7 is applied to the entire surface of the structured mask 22, not just in the areas that remain free of the structured mask 22. This results in cavities between the starting layer 6 and the foil 7, which are filled in a subsequent step, see FIG. 4.2, like the through-holes or cavities in the foil 7 by means of electroplating of an electrically conductive material 8. This step, shown in FIG. 4.2, can then be followed by the steps shown in FIGS. 5 to 13 and 5.1 to 13.1.

FIG. 3.3 shows a further alternative to the steps shown in FIGS. 3.1 and 3.2. The ion track-etched film 7 is also applied over the entire surface of the structured mask 22, but it is formed in such a way that it conforms to the contour of the structured mask 22 and is thus in contact with the starting layer 6 in the areas that remain free of the structured mask.

In addition, FIG. 13.2 shows a further embodiment example of a semiconductor arrangement 1. In contrast to the two other embodiment examples, this has two supports 23, which are each arranged centrally opposite the semiconductor components 10 and hold them in position. The recess 17 between the two semiconductor components 10 is arranged correspondingly offset to the two supports 23.

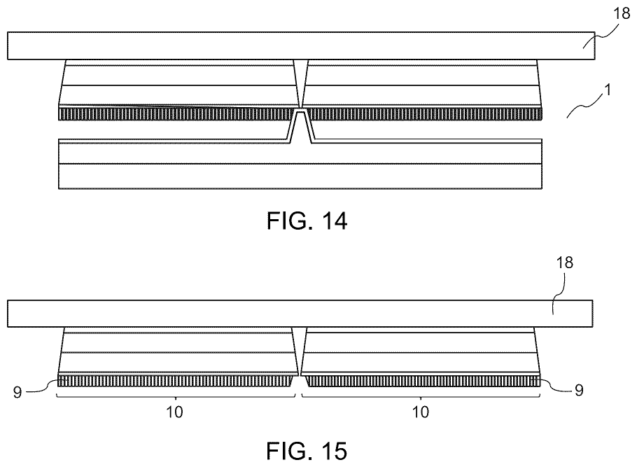

The semiconductor components 10 in the semiconductor arrangement 1 produced by means of the process steps shown can then be picked up with, for example, a transfer stamp and detached from the semiconductor arrangement 1 or the supports 23 in order to be subsequently transferred to a target substrate. The semiconductor arrangement 10 can serve as a donor substrate from which the semiconductor components 10 are transferred to a target substrate. FIGS. 14 to 19 show process steps of such a process for manufacturing an optoelectronic device 100 according to some aspects of the proposed principle.

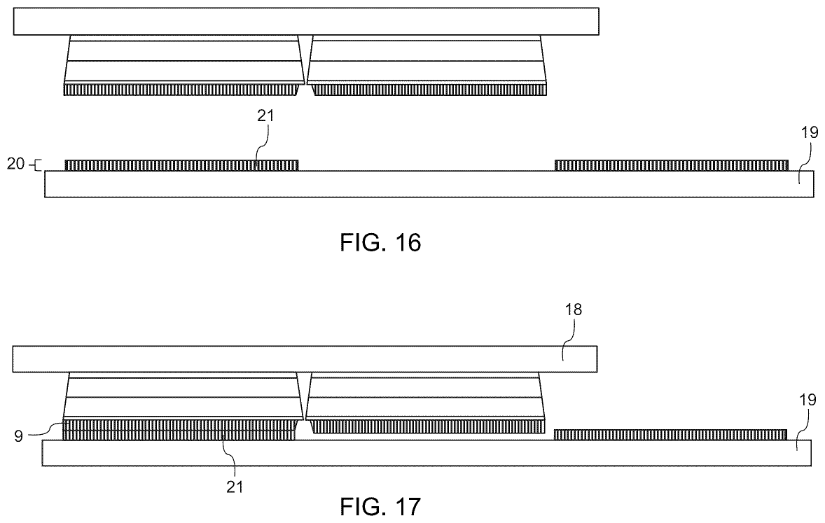

In a first step, as shown in FIG. 14, a transfer stamp 18 is placed on the contact layer 16 on a semiconductor arrangement 1 comprising two semiconductor components 10, as shown in FIG. 13. The semiconductor components are then lifted or torn off the semiconductor arrangement or the supports 23 of the semiconductor arrangement 1, as shown in FIG. 15, and the transfer stamp 18 with the semiconductor components 10 is positioned over a printed circuit board 19, as shown in FIG. 16.

The printed circuit board 19 has a contact structure 20 with a plurality of slightly raised contact surfaces 21 arranged on its top surface. Like the semiconductor components 1, the contact surfaces 21 on the top surface of the printed circuit board 19 have an electrically conductive nanowire layer, which can be formed in accordance with the proposed aspects.

The transfer stamp 18 with the semiconductor components 10 is positioned above the printed circuit board 19 in such a way that the nanowire layer 9 of a semiconductor component 10 is opposite a contact surface 21 on the top surface of the printed circuit board 19. In the case shown, there is a 1 to 1 assignment of the opposing nanowire layers 9 of the semiconductor components 10 with the contact surfaces 21 on the top surface of the printed circuit board 19, but several nanowire layers 9 of the semiconductor components 10 and contact surfaces 21 on the top surface of the printed circuit board 19 can also face each other at the same time.

In a further step, as shown in FIG. 17, the transfer stamp 18 with the semiconductor components 10 is lowered in the direction of the printed circuit board 19 and pressed onto the printed circuit board 19 or the contact structure 20. Due to the fact that the contact surfaces 21 protrude slightly above the surface of the printed circuit board 19, the nanowire layer 9 opposite each other and the contact surface 21 touch first when the transfer stamp 18 is lowered. The nanowire layer 9 of the adjacent semiconductor component, on the other hand, does not touch the top of the printed circuit board.

By depositing and pressing the semiconductor component 10 onto the contact surface 21, it is fixed to the contact surface 21. Due to the turf-like structure of the nanowire layers and the easy deformability of the nanowire layers, even a relatively small contact pressure is sufficient to generate a mechanical, thermal and electrical contact between the semiconductor component 10 and the contact surface 21. This results in the structures or nanowires of the nanowire layers interlocking and sliding into each other, thus creating a mechanical, thermal and electrical connection.

The depositing and pressing of the semiconductor component 10 onto the contact surface 21 essentially takes place without a temperature-induced process, which is why it can also be referred to as “cold welding” without an arc. The deformation of the metal structures, which leads to “cold welding”, can be carried out at or near room temperature.

As soon as the semiconductor component 10 is fixed on the contact surface 21, the transfer stamp 18 can be raised or lifted off again, and the fixed semiconductor component 10 remains on the contact surface 21. Then, as shown in FIG. 18, the transfer stamp 18 with the remaining semiconductor components 10 or, in the case shown, with the remaining semiconductor component 10 can be positioned opposite the printed circuit board 19 in such a way that the nanowire layer 9 of the remaining semiconductor component 10 is opposite a further contact surface 21. The transfer stamp 18 is then lowered in the direction of the printed circuit board 19 and pressed onto the printed circuit board 19 or the contact structure 20, so that the remaining semiconductor component 10 is fixed on the further contact surface 21.

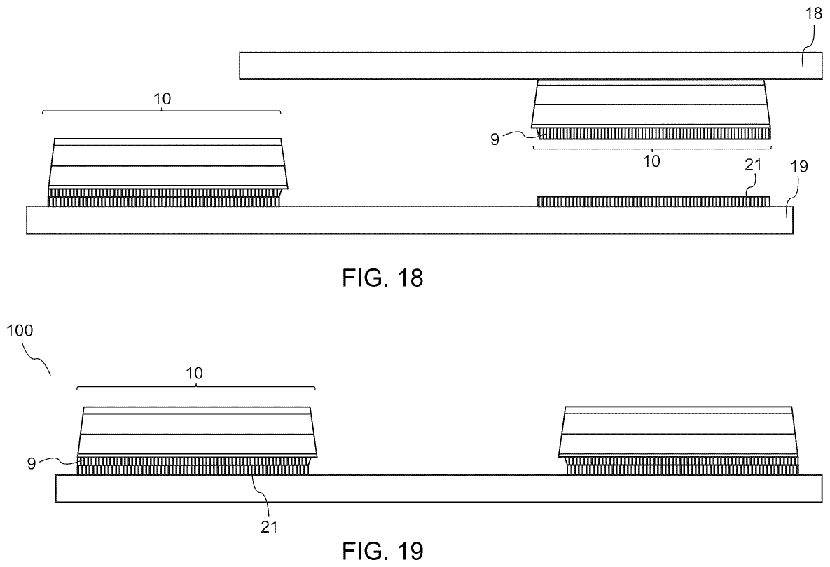

The result is the optoelectronic device 100 shown in FIG. 19.

1-31. (canceled)

32. A semiconductor arrangement comprising:
at least one semiconductor component comprising a functional layer stack, the functional layer stack comprising:
a first layer of a first conductivity type;
a second layer of a second conductivity type arranged on the first layer;
an active zone located between the first and the second layer; and
an electrically conductive nanowire layer, wherein the electrically conductive nanowire layer is arranged at least in regions on a side of the second layer facing away from the first layer; and
a holding layer with at least one elevation,
wherein the at least one semiconductor component is arranged on the at least one elevation such that a cavity is formed between the at least one semiconductor component and the holding layer, and
wherein the nanowire layer is at least partially exposed.

33. The semiconductor arrangement according to claim 32, wherein the at least one semiconductor component comprises a mesa structure.

34. The semiconductor arrangement according to claim 32, wherein the at least one semiconductor component comprises an electrically conductive layer on a side of the first layer facing away from the second layer.

35. The semiconductor arrangement according to claim 32, wherein the at least one semiconductor component further comprises a start layer arranged between the second layer and the nanowire layer.

36. The semiconductor arrangement according to claim 32, wherein the nanowire layer substantially covers an entire side of the second layer facing away from the first layer.

37. The semiconductor arrangement according to claim 32, wherein a plurality of nanowires is present separately from one another within the nanowire layer.

38. The semiconductor arrangement according to claim 32, further comprising at least two semiconductor components, which are arranged side by side on the at least one elevation, separated from each other by a recess.

39. The semiconductor arrangement according to claim 32, further comprising at least two semiconductor components, which are separated from each other by a recess and arranged next to each other on a separate elevation of the holding layer.

40. A method for manufacturing a semiconductor arrangement, the method comprising:
providing a functional layer stack comprising a carrier substrate, a first layer of a first conductivity type arranged on the carrier substrate, a second layer of a second conductivity type arranged on the first layer, and an active zone located between the first and second layers;
forming an electrically conductive nanowire layer at least in certain areas on a side of the second layer facing away from the carrier substrate;
forming a structured sacrificial layer on the nanowire layer with at least one opening, wherein the at least one opening extends at least through the sacrificial layer and at least partially through the nanowire layer;
forming a holding layer on the structured sacrificial layer, wherein the holding layer is arranged at least partially in the at least one opening;
structuring the functional layer stack to produce at least one semiconductor component such that at least one recess is formed by the functional layer stack; and
removing the sacrificial layer such that a cavity is formed between the at least one semiconductor component and the holding layer,
wherein the nanowire layer is at least partially exposed.

41. The method according to claim 40, further comprising forming a starting layer on the side of the second layer facing away from the carrier substrate before the nanowire layer is formed.

42. The method according to claim 40, wherein forming the nanowire layer comprises applying an ion track-etched film to the side of the second layer facing away from the carrier substrate.

43. The method according to claim 42, wherein forming the nanowire layer comprises electrodepositing an electrically conductive material on the ion track-etched film.

44. The method according to claim 40, wherein forming the nanowire layer comprises chemomechanically thinning the nanowire layer such that a plurality of nanowires are present in the nanowire layer separately from each other.

45. The method according to claim 40, further comprising forming a structured mask on the side of the second layer facing away from the carrier substrate before forming the nanowire layer, wherein the electrically conductive nanowire layer is subsequently formed on the side of the second layer facing away from the carrier substrate in regions, which remain free of the structured mask.

46. The method according to claim 42, wherein forming the structured sacrificial layer to form the at least one opening comprises an etching step by which regions of the sacrificial layer and the ion track etched film and/or the structured mask are removed.

47. The method according to claim 40, further comprising:
removing the carrier substrate; and
optionally forming an electrically conductive and at least semi-transparent contact layer on the side of the first layer facing away from the second layer.

48. The method according to claim 40, wherein structuring the functional layer stack comprises mesa etching the functional layer stack to produce the at least one semiconductor component.

49. The method according to claim 40, wherein the at least one opening through the sacrificial layer and the at least one recess through the functional layer stack are substantially directly opposite one another.

50. The method according to claim 40, wherein the at least one opening through the sacrificial layer and the at least one recess through the functional layer stack are arranged offset relative to one another.

51. A method for manufacturing an optoelectronic device, the method comprising:
providing the semiconductor arrangement according to claim 32;
lifting off the at least one semiconductor component from the at least one elevation; and
arranging the at least one semiconductor component on a first contact surface of a printed circuit board, the printed circuit board having a contact structure with a plurality of contact surfaces on its top surface.

52. The method according to claim 51, wherein at least the first contact surface comprises the electrically conductive nanowire layer.

53. The method according to claim 51, wherein lifting off the at least one semiconductor component is carried out by a transfer stamp.

54. The method according to claim 51, wherein arranging the at least one semiconductor component comprises fixing the at least one semiconductor component to the first contact surface by pressing the at least one semiconductor component onto the first contact surface.

55. The method according to claim 54, wherein fixing the at least one semiconductor component is substantially carried out without a temperature-induced process.

56. The method according to claim 53, wherein the semiconductor arrangement comprises a plurality of semiconductor components, and wherein at least a number of the plurality of semiconductor components are lifted off and are arranged to first contact surfaces of the printed circuit board.

57. An optoelectronic device comprising:
a printed circuit board comprising a contact structure with a plurality of contact surfaces on its top surface; and
a plurality of semiconductor components, each arranged on one of the plurality of contact surfaces,
wherein each of the semiconductor components comprises an electrically conductive nanowire layer at least in certain regions on a bottom surface facing the contact structure, and
wherein each electrically conductive nanowire layer is in electrically conductive connection with one of the contact surfaces on the top surface of the printed circuit board.

58. The optoelectronic device according to claim 57, wherein the contact surfaces on the top surface of the printed circuit board comprise an electrically conductive nanowire layer.

59. The optoelectronic device according to claim 57, wherein each of the semiconductor components comprises an electrically conductive and at least semi-transparent contact layer on a side of the semiconductor component opposite the printed circuit board.

60. The optoelectronic device according to claim 57, wherein each of the semiconductor components comprises a start layer formed between a functional layer stack of the semiconductor component and the nanowire layer.

61. The optoelectronic device according to claim 57, wherein the nanowire layer of each semiconductor component substantially covers an entire bottom surface of the respective semiconductor component facing the contact structure.

62. The optoelectronic device according to claim 57, wherein a plurality of nanowires is present separately from one another within each nanowire layer.
